(19) United States
(12) Patent Application Publication
(10) Pub. No.: US 2026/0247606 A1
(43) Pub. Date: Aug. 20, 2026

(54) SEMICONDUCTOR DEVICE WITH SUPPORTING LAYERS AND METHOD FOR FABRICATING THE SAME

(71) Applicant: NANYA TECHNOLOGY CORPORATION, NEW TAIPEI CITY (TW)

(72) Inventor: JING HSU, NEW TAIPEI CITY (TW)

(21) Appl. No.: 19/057,214

(22) Filed: Feb. 19, 2025

(51) Int. Cl. H10B 12/00

(52) U.S. Cl. CPC H10B 12/34; H10B 12/053

(57) ABSTRACT

The present application discloses a semiconductor device and a method for fabricating the semiconductor device. The semiconductor device includes a substrate including at least four active portions, and at least two supporting portions connecting the at least four active portions. Two of the active portions are arranged along a first direction and separated by an opening. The other two of the active portions are arranged along a second direction perpendicular to the first direction, separated by the opening, and with the two of the active portions interposed therebetween. The other two of the active portions arranged along the second direction and the two of the active portions arranged along the first direction are separated by a plurality of recesses. The supporting portions are arranged along the second direction, separated by the opening, and respectively connecting to three of the active portions.

### TECHNICAL FIELD

The present disclosure relates to a semiconductor device and a method for fabricating the semiconductor device, and more particularly, to a semiconductor device with supporting layers and a method for fabricating the semiconductor device with the supporting layers.

### DISCUSSION OF THE BACKGROUND

Semiconductor devices are used in a variety of electronic applications, such as personal computers, cellular telephones, digital cameras, and other electronic equipment. The dimensions of semiconductor devices are continuously being scaled down to meet the increasing demand of computing ability. However, a variety of issues arise during the scaling-down process, and such issues are continuously increasing. Therefore, challenges remain in achieving improved quality, yield, performance, and reliability and reduced complexity.

This Discussion of the Background section is provided for background information only. The statements in this Discussion of the Background are not an admission that the subject matter disclosed in this section constitutes prior art to the present disclosure, and no part of this Discussion of the Background section may be used as an admission that any part of this application, including this Discussion of the Background section, constitutes prior art to the present disclosure.

### SUMMARY

One aspect of the present disclosure provides a semiconductor device including a substrate including at least four active portions, and at least two supporting portions connecting the at least four active portions. Two of the at least four active portions are arranged along a first direction and separated by an opening in a top-view perspective. The other two of the at least four active portions are arranged along a second direction perpendicular to the first direction, separated by the opening, and with the two of the at least four active portions arranged along the first direction interposed therebetween in a top-view perspective. The other two of the at least four active portions arranged along the second direction and the two of the at least four active portions arranged along the first direction are separated by a plurality of recesses in a top-view perspective. The at least two supporting portions are arranged along the second direction, separated by the opening, and respectively connecting to three of the at least four active portions in a top-view perspective.

Another aspect of the present disclosure provides a semiconductor device including a substrate including four active portions arranged in a rhombus-shaped configuration in a top-view perspective, and two supporting portions centrally positioned and surrounded by the four active portions in a top-view perspective, with the two supporting portions respectively connecting three of the four active portions.

Another aspect of the present disclosure provides a method for fabricating a semiconductor device including providing a substrate; performing a first substrate-etching process using a primary mask layer as a mask to form a plurality of recesses in the substrate; forming a secondary mask layer on the substrate and filling the plurality of recesses; performing a second substrate-etching process using the secondary mask layer as a mask to form a plurality of openings in the substrate and configure a plurality of active portions and a plurality of supporting portions, wherein, in a top-view perspective, the plurality of active portions are arranged along a first direction and a second direction perpendicular to the first direction, the plurality of active portions arranged along the first direction are separated by the plurality of openings, the plurality of active portions arranged along the second direction are separated by the plurality of recesses, and the plurality of supporting portions surround the plurality of openings and respectively connects three of the plurality of active portions; performing an oxygen treatment to turn the plurality of supporting portions into a removable layer; and removing the removable layer to turn the plurality of recesses into a plurality of trenches.

Due to the design of the semiconductor device of the present disclosure, the plurality of supporting portions SP may provide additional structural stability to the plurality of active portions AP, preventing their collapse. Consequently, the yield and reliability of the semiconductor device 1A may be significantly improved.

The foregoing has outlined rather broadly the features and technical advantages of the present disclosure in order that the detailed description of the disclosure that follows may be better understood. Additional features and advantages of the disclosure will be described hereinafter, and form the subject of the claims of the disclosure. It should be appreciated by those skilled in the art that the conception and specific embodiment disclosed may be readily utilized as a basis for modifying or designing other structures or processes for carrying out the same purposes of the present disclosure. It should also be realized by those skilled in the art that such equivalent constructions do not depart from the spirit and scope of the disclosure as set forth in the appended claims.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates, in a flowchart diagram form, a method for fabricating a semiconductor device in accordance with one embodiment of the present disclosure;

FIG. 2 illustrates, in a schematic top-view diagram, an intermediate semiconductor device in accordance with one embodiment of the present disclosure;

FIGS. 3 to 6 are schematic cross-sectional view diagrams taken along lines A-A′, B-B′, and C-C′ in FIG. 2 illustrating part of a flow for fabricating the semiconductor device in accordance with one embodiment of the present disclosure;

FIG. 7 illustrates, in a schematic top-view diagram, an intermediate semiconductor device in accordance with one embodiment of the present disclosure;

FIGS. 8 and 9 are schematic cross-sectional view diagrams taken along lines A-A′, B-B′, and C-C′ in FIG. 7 illustrating part of the flow for fabricating the semiconductor device in accordance with one embodiment of the present disclosure;

FIG. 10 illustrates, in a schematic top-view diagram, an intermediate semiconductor device in accordance with one embodiment of the present disclosure;

FIGS. 11 and 12 are schematic cross-sectional view diagrams taken along lines A-A′, B-B′, and C-C′ in FIG. 10 illustrating part of the flow for fabricating the semiconductor device in accordance with one embodiment of the present disclosure;

FIG. 13 illustrates, in a schematic top-view diagram, an intermediate semiconductor device in accordance with one embodiment of the present disclosure; and

FIGS. 14 to 20 are schematic cross-sectional view diagrams taken along lines A-A′, B-B′, and C-C′ in FIG. 13 illustrating part of the flow for fabricating the semiconductor device in accordance with one embodiment of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

It should be understood that when an element or layer is referred to as being “connected to” or “coupled to” another element or layer, it can be directly connected to or coupled to another element or layer, or intervening elements or layers may be present.

It should be understood that, although the terms first, second, etc. may be used herein to describe various elements, these elements should not be limited by these terms. Unless indicated otherwise, these terms are only used to distinguish one element from another element. Thus, for example, a first element, a first component or a first section discussed below could be termed a second element, a second component or a second section without departing from the teachings of the present disclosure.

Unless the context indicates otherwise, terms such as “same,” “equal,” “planar,” or “coplanar,” as used herein when referring to orientation, layout, location, shapes, sizes, amounts, or other measures do not necessarily mean an exactly identical orientation, layout, location, shape, size, amount, or other measure, but are intended to encompass nearly identical orientation, layout, location, shapes, sizes, amounts, or other measures within acceptable variations that may occur, for example, due to manufacturing processes. The term “substantially” may be used herein to reflect this meaning. For example, items described as “substantially the same,” “substantially equal,” or “substantially planar,” may be exactly the same, equal, or planar, or may be the same, equal, or planar within acceptable variations that may occur, for example, due to manufacturing processes.

In the present disclosure, a semiconductor device generally means a device which can function by utilizing semiconductor characteristics, and an electro-optic device, a light-emitting display device, a semiconductor circuit, and an electronic device are all included in the category of the semiconductor device.

It should be noted that, in the description of the present disclosure, above (or up) corresponds to the direction of the arrow of the Z direction, and below (or down) corresponds to the opposite direction of the arrow of the Z direction.

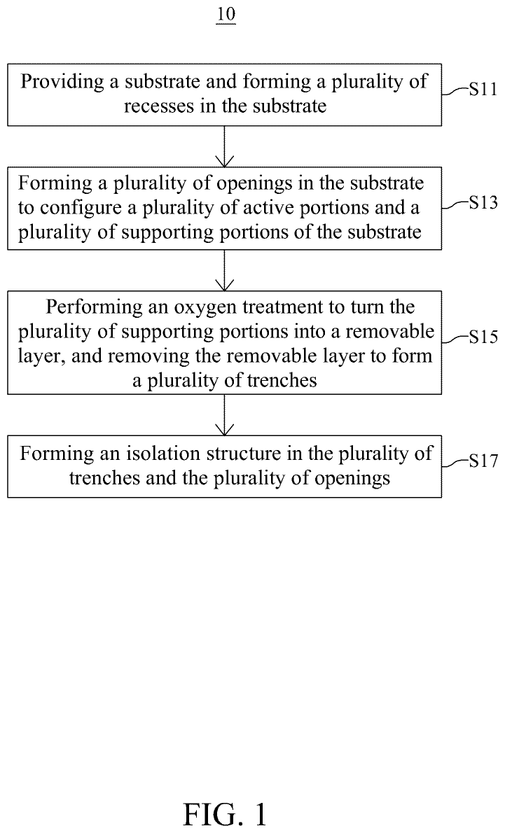

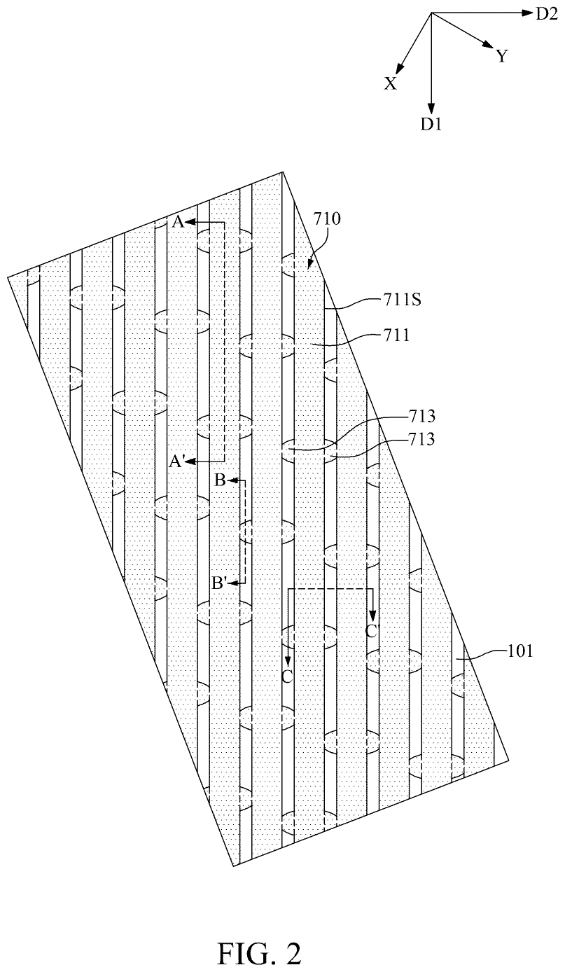

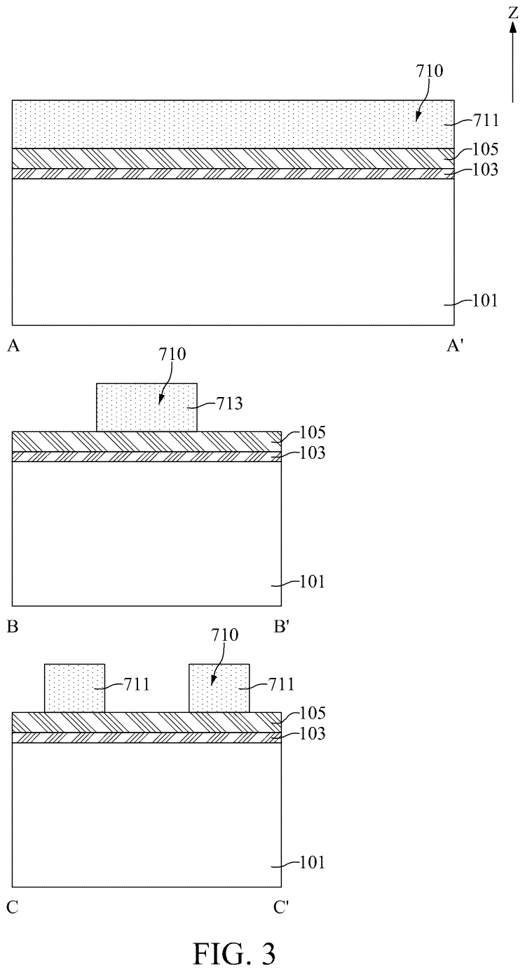

FIG. 1 illustrates, in a flowchart diagram form, a method 10 for fabricating a semiconductor device 1A in accordance with one embodiment of the present disclosure. FIG. 2 illustrates, in a schematic top-view diagram, an intermediate semiconductor device in accordance with one embodiment of the present disclosure. FIGS. 3 to 6 are schematic cross-sectional view diagrams taken along lines A-A′, B-B′, and C-C′ in FIG. 2 illustrating part of a flow for fabricating the semiconductor device 1A in accordance with one embodiment of the present disclosure.

With reference to FIGS. 1 to 6, at step S11, a substrate 101 may be provided and a plurality of recesses R1 may be formed in the substrate 101.

With reference to FIGS. 2 and 3, the substrate 101 may include a bulk semiconductor substrate. The bulk semiconductor substrate may be formed of, for example, an elementary semiconductor, such as silicon or germanium; a compound semiconductor, such as silicon germanium, silicon carbide, gallium arsenide, gallium phosphide, indium phosphide, indium arsenide, indium antimonide, or other III-V compound semiconductor or II-VI compound semiconductor; or combinations thereof. In some embodiments, the substrate 101 may be formed of, for example, silicon, germanium, silicon germanium, silicon carbon, silicon germanium carbon, gallium, gallium arsenide, indium arsenide, indium phosphorus, or other IV-IV, III-V or II-VI semiconductor materials. In some embodiments, the substrate 101 may be formed of, for example, InSb, GaN, GaP, GaSb, GaAsP, GaAsN, GaInAs, GaInP, AlGaAs, AlGaIn, AlGaP, AlGaInP, InGaAs, InGaN, InGaP, InGaSb, InAsSb, AlN, AlGaN, ZnSe, diamond (C), or Ga₂O₃. In some embodiments, the substrate 101 may be doped with various types of dopants, such as, but not limited to, boron, aluminum, gallium, indium, arsenic, or phosphorus.

In some embodiments, the substrate 101 may include a semiconductor-on-insulator structure which consists of, from bottom to top, a handle substrate, an insulator layer, and a topmost semiconductor material layer. The handle substrate and the topmost semiconductor material layer may be formed of the same material as the bulk semiconductor substrate aforementioned. The insulator layer may be a crystalline or non-crystalline dielectric material such as an oxide and/or nitride. For example, the insulator layer may be a dielectric oxide such as silicon oxide. For another example, the insulator layer may be a dielectric nitride such as silicon nitride or boron nitride. For yet another example, the insulator layer may include a stack of a dielectric oxide and a dielectric nitride such as a stack of, in any order, silicon oxide and silicon nitride or boron nitride. The insulator layer may have a thickness between about 10 nm and 200 nm.

In some embodiments, the crystal orientation of the substrate 101 (or the top semiconductor layer) may be <100>, <110>, or <111>. In the present embodiment, the substrate 101 may be formed of silicon.

It should be noted that, the term “about” modifying the quantity of an ingredient, component, or reactant of the present disclosure employed refers to variation in the numerical quantity that can occur, for example, through typical measuring and liquid handling procedures used for making concentrates or solutions. Furthermore, variation can occur from inadvertent error in measuring procedures, differences in the manufacture, source, or purity of the ingredients employed to make the compositions or carry out the methods, and the like. In one aspect, the term “about” means within 10% of the reported numerical value. In another aspect, the term “about” means within 5% of the reported numerical value. Yet, in another aspect, the term “about” means within 10, 9, 8, 7, 6, 5, 4, 3, 2, or 1% of the reported numerical value.

With reference to FIGS. 2 and 3, a bottom hard mask layer 103 may be formed on the substrate 101. In the bottom hard mask layer 103 may be formed of, for example, silicon oxide. In some embodiments, the bottom hard mask layer 103 may be formed by performing a rapid thermal oxidation to the substrate 101 in an oxide/oxynitride atmosphere. In some embodiments, the temperature of the rapid thermal oxidation may be about 1000° C. It should be noted that the bottom hard mask layer 103 is not shown in top-view diagrams for clarity.

With reference to FIGS. 2 and 3, a top hard mask layer 105 may be formed on the bottom hard mask layer 103. In some embodiments, the top hard mask layer 105 may be formed of, for example, silicon oxide. In some embodiments, the top hard mask layer 105 may be formed by, for example, chemical vapor deposition, plasma enhanced chemical vapor deposition. For example, the top hard mask layer 105 may be deposited by chemical vapor deposition using a silicate or silicon source, a number of doping sources, and an ozone source. In some embodiments, the doping sources may be optional. In some embodiments, the doping sources may be, for example, triethylborate, triethylphosphate, triethyphosphite, trimethylphosphate, or trimethylphosphite. In some embodiments, the silicate or silicon source may be, for example, tetramethylorthosilicate. The doping sources may result in impurity atoms such as phosphorus or boron in the top hard mask layer 105. It should be noted that the top hard mask layer 105 is not shown in top-view diagrams for clarity.

With reference to FIGS. 2 and 3, a primary mask layer 710 may be formed on the top hard mask layer 105. In some embodiments, the primary mask layer 710 may be a photoresist layer. The primary mask layer 710 may include a pattern including a plurality of body portions 711 and a plurality of connecting portions 713. For clarity and convenience, only one body portion 711 and two connecting portions 713 are described here.

In a top-view perspective, the body portion 711 may have a rectangular (or line-shaped) cross-sectional profile that extends along a direction D1. The direction D1 is slanted relative to both the X and Y directions. The two connecting portions 713 may be positioned between two sides 711S of the body portion 711 and aligned along a direction D2, which is perpendicular to the direction D1. State differently, the two connecting portions 713 may be disposed separately with the body portion 711 interposed therebetween.

In some embodiments, the plurality of body portions 711 may be alternatively arranged along the second direction D2. The plurality of connecting portions 713 may be arranged between the plurality of body portions 711 and connecting adjacent pairs of the plurality of body portions 711. An adjacent pair of the plurality of body portions 711 refers to two body portions 711 next to each other.

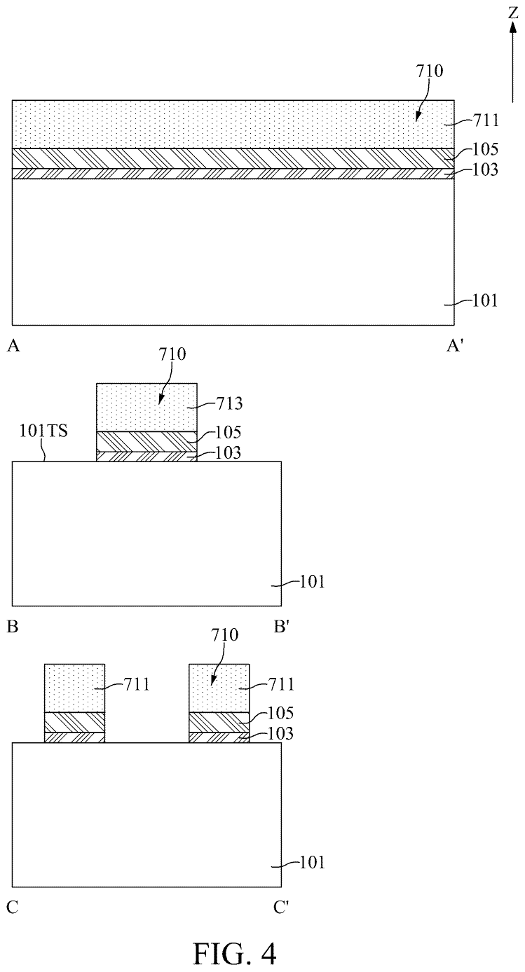

With reference to FIG. 4, a hard mask etching process may be performed using the primary mask layer 710 as the mask to remove a portion of the top hard mask layer 105 and a portion of the bottom hard mask layer 103. After the hard mask etching process, the pattern of the primary mask layer 710 may be transferred to the bottom hard mask layer 103 and the top hard mask layer 105.

In some embodiments, the etch rate of the top hard mask layer 105 (or the bottom hard mask layer 103) of the hard mask etching process may be faster than the etch rate of the substrate 101 of the hard mask etching process. For example, the etch rate ratio of the top hard mask layer 105 (or the bottom hard mask layer 103) to the substrate 101 may be between about 100:1 and about 2:1 during the hard mask etching process. For another example, the etch rate ratio of the top hard mask layer 105 (or the bottom hard mask layer 103) to the substrate 101 may be between about 100:1 and about 10:1 during the hard mask etching process.

In some embodiments, the primary mask layer 710 may be removed after completing the pattern transfer. In some embodiments, the removal of the primary mask layer 710 may be, for example, an ashing process or other applicable semiconductor processes.

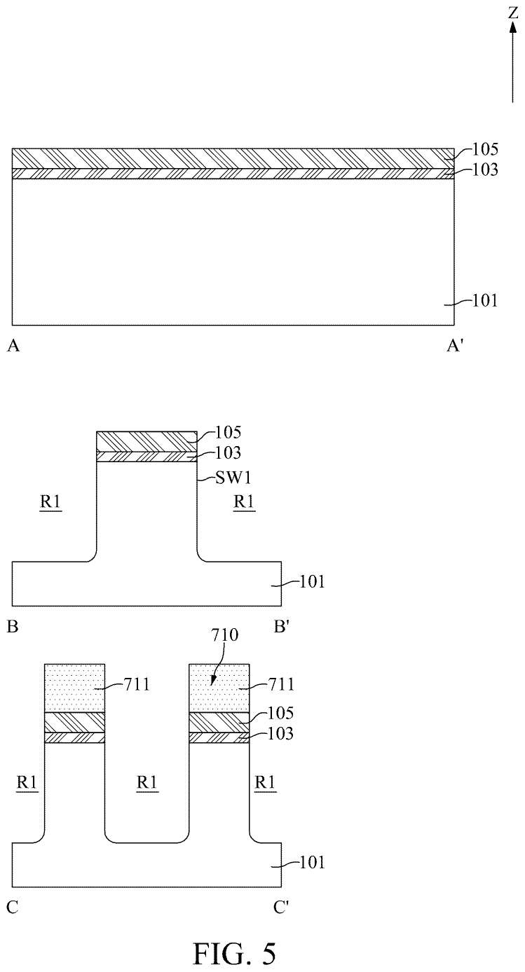

With reference to FIG. 5, an etching process (also referred to as the first substrate-etching process) may be performed, utilizing the bottom hard mask layer 103 and the top hard mask layer 105 as masks, to remove a portion of the substrate 101. This process results in the formation of the plurality of recesses R1.

It should be noted that, in the description of the present disclosure, a surface is “substantially vertical” if there exists a vertical plane from which the surface does not deviate by more than three times the root mean square roughness of the surface.

In some embodiments, the etch rate of the substrate 101 of the first substrate-etching process may be faster than the etch rate of the top hard mask layer 105 (or the bottom hard mask layer 103) of the first substrate-etching process. For example, the etch rate ratio of the substrate 101 to the top hard mask layer 105 (or the bottom hard mask layer 103) may be between about 100:1 and about 2:1 during the first substrate-etching process. For another example, the etch rate ratio of the substrate 101 to the top hard mask layer 105 (or the bottom hard mask layer 103) may be between about 100:1 and about 10:1 during the first substrate-etching process.

In some embodiments, a post-etching cleaning process may be performed after the formation of the plurality of recesses R1. The post-etching cleaning process may include three stages with inter-stage rinses between stages. Detailedly, during the first stage of the post-etching cleaning process, a first cleaning solution may be applied to the intermediate semiconductor device after the formation of the plurality of recesses R1. The first cleaning solution may be rinsed by the first inter-stage rinse. During the second stage of the post-etching cleaning process, a second cleaning solution may be applied to the intermediate semiconductor device and the second cleaning solution may be subsequently rinsed by a second inter-stage rinse. During the third stage of the cleaning process, a third cleaning solution may be applied to the intermediate semiconductor device and then be rinsed by a post-stage rinse.

In some embodiments, during the first stage of the post-etching cleaning process, the intermediate semiconductor device may be spun at a rate between about 10 rpm and about 2000 rpm or between about 100 rpm and 1000 rpm. The first cleaning solution may be sprayed onto the intermediate semiconductor device to cover the entire front side of the intermediate semiconductor device. Simultaneously to applying the first cleaning solution onto the front side of the intermediate semiconductor device, water or other suitable solution may be applied to the backside of the intermediate semiconductor device to clean the backside of the intermediate semiconductor device.

In some embodiments, the first cleaning solution may include diluted hydrofluoric acid. The concentration of the first cleaning solution may be between about 5 parts deionized water to one part hydrofluoric acid and about 1000 parts deionized water to one part hydrofluoric acid, about 300 parts deionized water to one part hydrofluoric acid, or about 50 parts deionized water to one part hydrofluoric acid. Generally, the front side of the intermediate semiconductor device may be exposed to the first cleaning solution for a time sufficient to etch either a sacrificial oxide (typically around 50 angstroms to 200 angstroms) or a native oxide (typically around 10 angstroms.) In some embodiments, the process time of the first stage of the cleaning process may be between about 20 seconds and about 50 seconds, about 40 seconds, or about 30 seconds. In some embodiments, the process time of the first stage of the post-etching cleaning process may be between about 1 minutes and about 5 minutes.

In some embodiments, the first cleaning solution may include fluoride compound(s), organic acid salt(s), and/or glyoxylic acid.

The fluorine compound(s) may be contained in the first cleaning solution as a component for removing the etching residue of the trench etching process. Examples of the fluorine compound(s) may include hydrofluoric acid and ammonium or amine fluoride salts such as, for example, ammonium fluoride, ammonium hydrogen fluoride, methylamine hydrofluoride, ethylamine hydrofluoride, propylamine hydrofluoride, tetramethylammonium fluoride, tetraethylammonium fluoride, ethanolamine hydrofluoride, methylethanolamine hydrofluoride, dimethylethanolamine hydrofluoride, and triethylenediamine hydrofluoride. In some embodiments, the concentration of the fluorine compound(s) in the first cleaning solution may be determined according to the composition of the etching residue. For example, the concentration of the fluorine compound(s) may be between about 0.1 mass % and about 5 mass % of the entire composition of the first cleaning solution, or between about 0.2 mass % and about 3 mass % of the entire composition of the first cleaning solution.

The organic acid salt(s) may include, for example, ammonium oxalate, ammonium tartrate, ammonium citrate, and ammonium acetate. The organic acid salt(s) may act as a pH adjusting agent(s) or buffer agent(s) in the first cleaning solution. The concentration of the organic acid salt(s) may be between about 0.1 mass % and about 10 mass % of the entire composition of the first cleaning solution, or between about 0.3 mass % and about 5 mass % of the entire composition of the first cleaning solution.

The glyoxylic contained in the first cleaning solution may serve as a corrosion inhibitor.

In some embodiments, the first cleaning solution may further include a resist removal component. Examples of the resist removal component include tetramethylammonium hydroxide and/or monomethanolamine.

The first inter-stage rinse may be performed after the first stage of the post-etching cleaning process. During the first inter-stage rinse, the intermediate semiconductor device after the first stage of the post-etching cleaning process may be rotated at between about 10 rpm and about 1000 rpm while being rinsed with deionized water. In some embodiments, the rinse temperature may be between about 19° C. and about 23° C. In some embodiments, the process time of the first inter-stage rinse may be between about 20 seconds and about 50 seconds, or about 30 seconds.

In some embodiments, the deionized water used for the first inter-stage rinse may be oxygenated or ozonated by dissolving oxygen gas or ozone gas before rinsing the intermediate semiconductor device. Dissolved oxygen or ozone may be added to the deionized water in a concentration of greater than 1 ppm to serve as an oxidant. For example, the concentration of dissolved oxygen or ozone may be between about 1 ppm and about 200 ppm or between about 2 ppm and about 20 ppm. For another example, the deionized water may be saturated with dissolved oxygen or ozone. Alternatively, hydrogen peroxide may be added to the deionized water in a concentration of greater than 100 ppm to serve as an oxidant. Whichever oxidant is used, it should have an oxidation potential sufficient to oxidize the most noble metal in the solution. Copper (Cu²⁺), with a standard reduction potential of 0.3V, is usually the most noble metal present. Therefore, a standard reduction potential of greater than 0.5V is desired. Oxygen or ozone will solvate the metal ions and prevent precipitation by oxidizing the metal ions that are in solution. This will help decrease the processing time by making the first inter-stage rinse more effective.

In some embodiments, the deionized water used for the first inter-stage rinse may be carbon dioxide dissolved into it to dissipate static electricity that builds up in the deionized water. Static electricity builds up in the deionized water may originate from the rotation of the intermediate semiconductor device. The dissolved carbon dioxide may also make the deionized water more acidic and therefore reduces any metallic contamination. In some embodiments, carbon dioxide may be dissolved into the deionized water in an amount sufficient to dissipate static electricity. For example, the amount of carbon dioxide dissolved into the deionized water may be sufficient to decrease the resistivity of the deionized water to less than 5 Megaohm·cm.

In some embodiments, the deionized water used for the first inter-stage rinse may have isopropyl alcohol, or any other liquid with a surface tension lower than that of the deionized water, added to it. Isopropyl alcohol may aid by making the deionized water spread out over the front side of the intermediate semiconductor device so that the chemicals are removed more quickly. Isopropyl alcohol may also help the rinse spin off of the intermediate semiconductor device during spinning. Alternatively, isopropyl alcohol vapor may be blown onto the front side of the intermediate semiconductor device while rinsing to assist the first inter-stage rinse.

In some embodiments, during the second stage of the post-etching cleaning process, the intermediate semiconductor device after the first inter-stage rinse may be spun at a rate between about 10 rpm and about 2000 rpm or between about 100 rpm and 1000 rpm. The second cleaning solution may be sprayed onto the intermediate semiconductor device to cover the entire front side of the intermediate semiconductor device. Simultaneously to applying the second cleaning solution onto the front side of the intermediate semiconductor device, water or other suitable solution may be applied to the backside of the intermediate semiconductor device to clean the backside of the intermediate semiconductor device.

In some embodiments, the second cleaning solution may be an alkaline solution including, for example, aqueous solutions of inorganic compounds such as sodium hydroxide, potassium hydroxide and ammonium hydroxide, and aqueous solution of organic compounds such as tetramethylammonium hydroxide and choline. The second cleaning solution may also include hydrogen peroxide. The purpose of the ammonium hydroxide and the hydrogen peroxide in the second cleaning solution is to remove particles and residual organic contaminants from the front side of the intermediate semiconductor device.

For example, in the present embodiment, the second cleaning solution may include ammonium hydroxide, hydrogen peroxide, and water. The ammonium hydroxide, hydrogen peroxide, and water may be present in concentrations defined by dilution ratios of between 5/1/1 to 1000/1/1, respectively. In some embodiments, the ammonium hydroxide/hydrogen peroxide ratio may vary between 0.05/1 and 5/1. In some embodiments, no hydrogen peroxide is used at all. The ammonium hydroxide in the second cleaning solution would be from a solution of 28-29% w/w of ammonia to water. The hydrogen peroxide in the second cleaning solution would be from a solution of 31-32% w/w of hydrogen peroxide to water. The pH of the second cleaning solution may be between about 9 and 12 or between about 10 and 11 due to the ammonium hydroxide and the hydrogen peroxide.

In some embodiments, the second cleaning solution may further include dissolved hydrogen gas. The dissolved hydrogen gas in the second cleaning solution may provide cavitation (bubble creation) to the second cleaning solution. Providing cavitation to the second cleaning solution may enhance the post-etching cleaning process. In some embodiments, the concentration of the dissolved hydrogen gas may be between about 0.01 mg/L and about 5 mg/L or between about 0.1 mg/L and about 5 mg/L. In some embodiments, other suitable cavitation gases such as nitrogen, helium, Argon, or oxygen may also be used. For example, dissolved oxygen having concentration between about 1 mg/L and about 20 mg/L may be used in the second cleaning solution.

In some embodiments, the process time of the second stage of the post-etching cleaning process may be between about 30 seconds and about 100 seconds, between about 30 seconds and 90 seconds, or between about 30 seconds and about 60 seconds. In some embodiments, the temperature of the second cleaning solution may be between about 40° C. and about 85° C.

The second inter-stage rinse may be performed after the second stage of the post-etching cleaning process. The second inter-stage rinse may be performed with a procedure similar to the first inter-stage rinse, and descriptions thereof are not repeated herein.

In some embodiments, during the third stage of the post-etching cleaning process, the intermediate semiconductor device after the second inter-stage rinse may be spun at a rate between about 10 rpm and about 2000 rpm or between about 100 rpm and 1000 rpm. The third cleaning solution may be sprayed onto the intermediate semiconductor device to cover the entire front side of the intermediate semiconductor device. Simultaneously to applying the third cleaning solution onto the front side of the intermediate semiconductor device, water or other suitable solution may be applied to the backside of the intermediate semiconductor device to clean the backside of the intermediate semiconductor device.

In some embodiments, the third cleaning solution may be an acidic solution including, for example, aqueous solution of inorganic acids such as hydrochloric acid, hydrofluoric acid, sulfuric acid and nitric acid, and aqueous solution of organic acids such as oxalic acid, citric acid, malonic acid, malic acid, fumaric acid and maleic acid. In some embodiments, the third cleaning solution may also include hydrogen peroxide. The concentration of the acidic solution may be between about 0.001% and about 10% by weight or between about 0.01% and about 5% by weight. When the concentration is too low, the washing effect may not be obtained sufficiently. When the concentration is too high, metal-corrosion of the washing apparatus or the other related apparatus may occur.

A post-stage rinse may be performed after the third stage of the post-etching cleaning process. The post-stage rinse may be performed with a procedure similar to the first inter-stage rinse, and descriptions thereof are not repeated herein.

In some embodiments, the second stage and the third stage of the post-etching cleaning process may be optional. In other words, only the first stage of the post-etching cleaning process may be performed. In some embodiments, the third stage of the post-etching cleaning process may be optional. In other words, only the first stage and the second stage of the post-etching cleaning process may be performed.

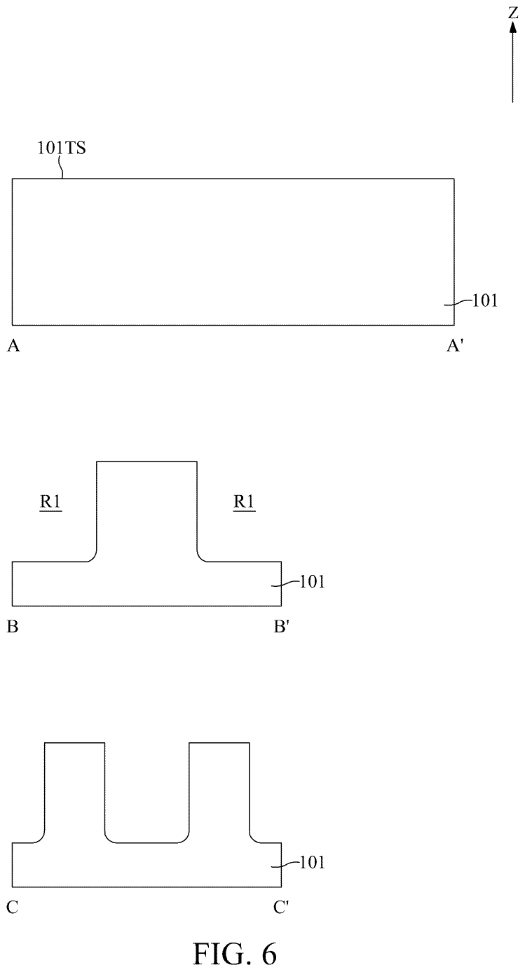

With reference to FIG. 6, the top hard mask layer 105 and the bottom hard mask layer 103 may be removed by, for example, an etching process such as a wet etching process or a dry etching process. In the present embodiment, the top hard mask layer 105 and the bottom hard mask layer 103 may be removed by wet etching process. In some embodiments, the etch rate ratio of the top hard mask layer 105 (or the bottom hard mask layer 103) to the substrate 101 may be between about 100:1 and about 1.05:1, between about 15:1 and about 2:1, or between about 10:1 and about 2:1 during the etching process.

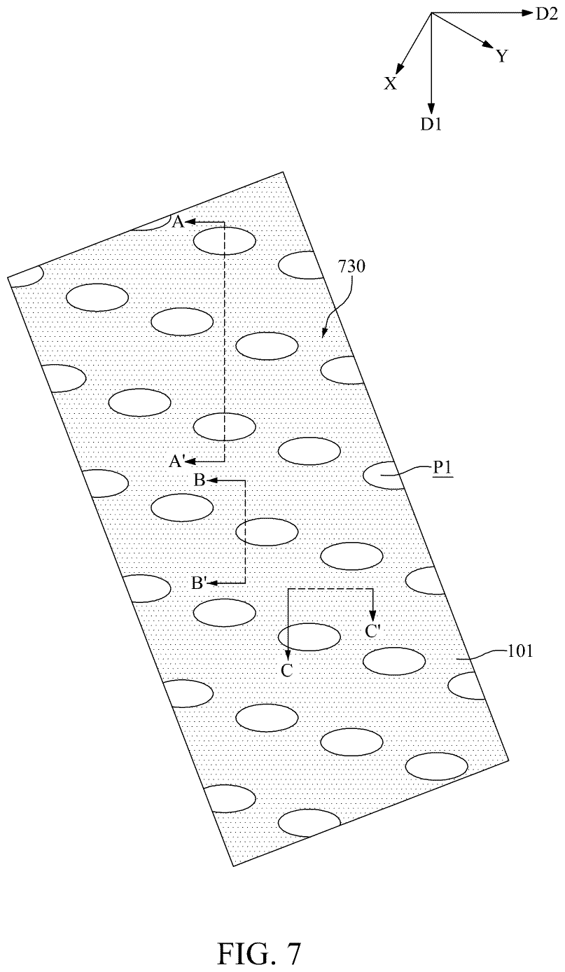

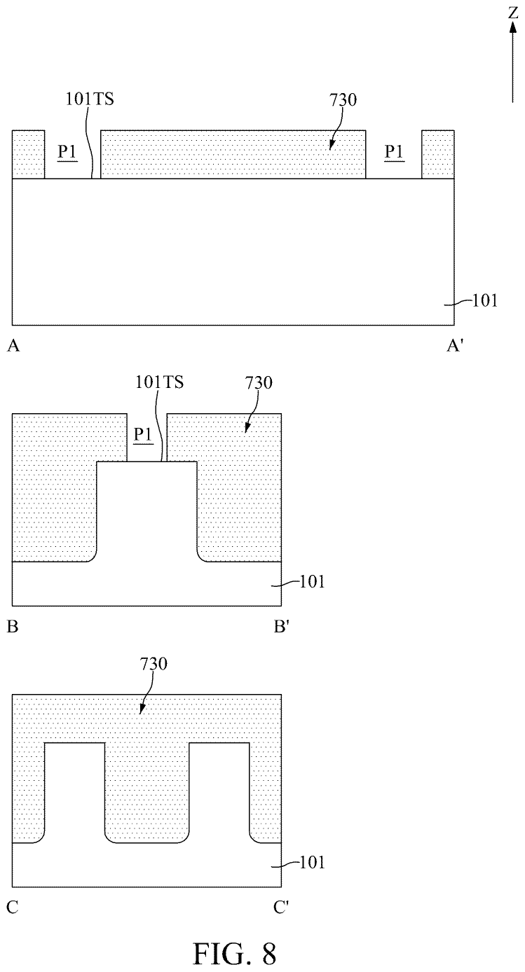

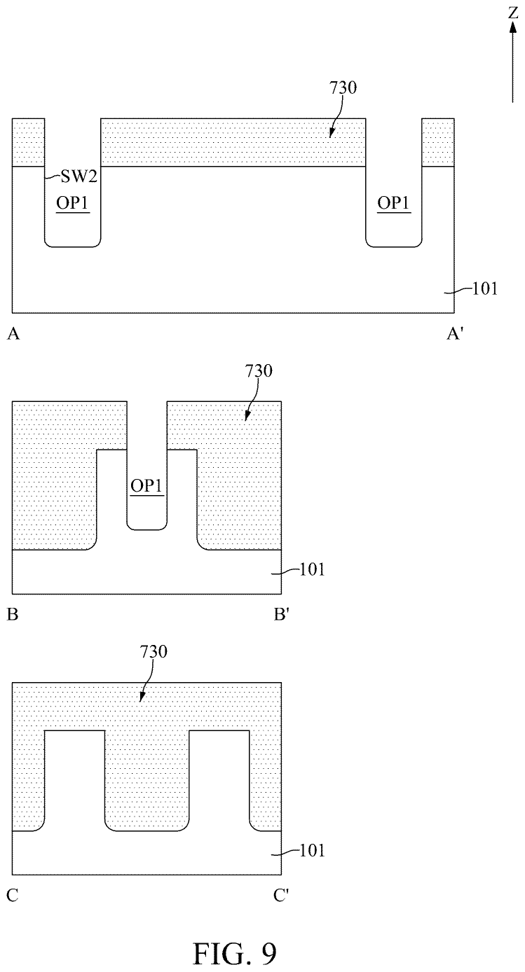

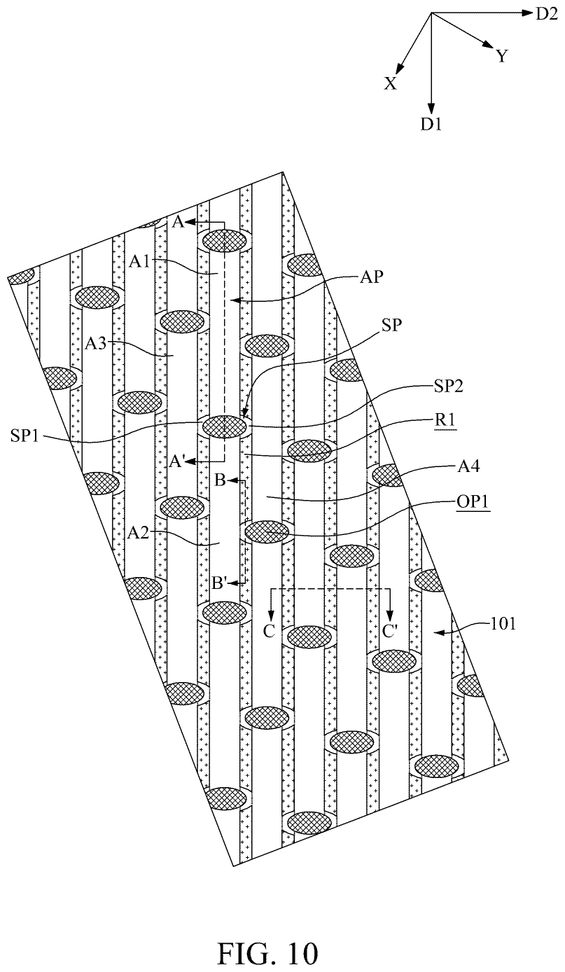

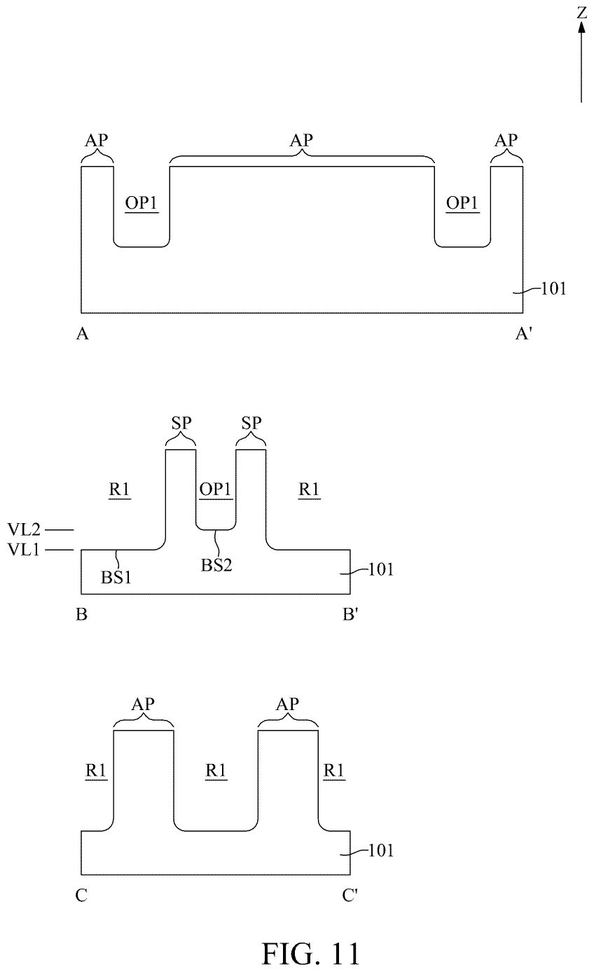

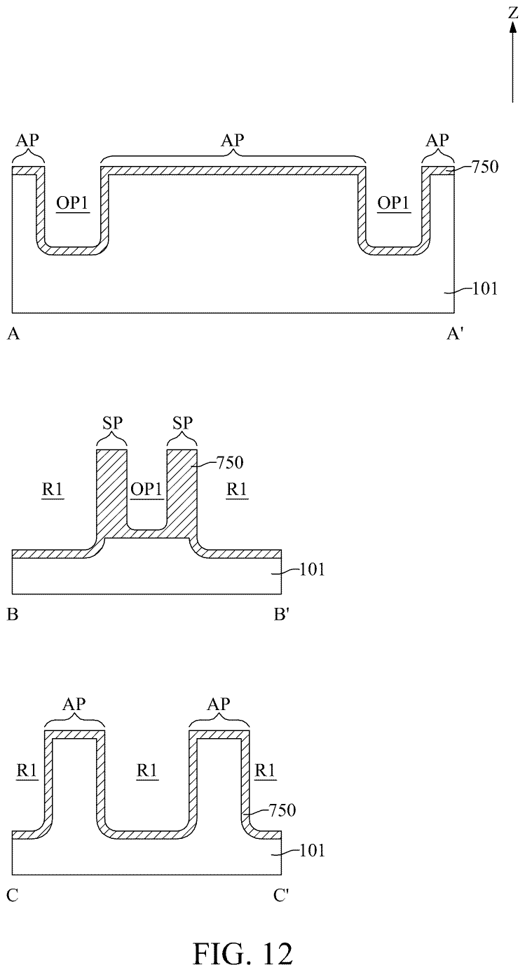

FIG. 7 illustrates, in a schematic top-view diagram, an intermediate semiconductor device in accordance with one embodiment of the present disclosure. FIGS. 8 and 9 are schematic cross-sectional view diagrams taken along lines A-A′, B-B′, and C-C′ in FIG. 7 illustrating part of the flow for fabricating the semiconductor device 1A in accordance with one embodiment of the present disclosure. FIG. 10 illustrates, in a schematic top-view diagram, an intermediate semiconductor device in accordance with one embodiment of the present disclosure. FIGS. 11 and 12 are schematic cross-sectional view diagrams taken along lines A-A′, B-B′, and C-C′ in FIG. 10 illustrating part of the flow for fabricating the semiconductor device 1A in accordance with one embodiment of the present disclosure.

With reference to FIG. 1 and FIGS. 7 to 11, at step S13, a plurality of openings OP1 may be formed in the substrate 101 to configure a plurality of active portions AP and a plurality of supporting portions SP of the substrate 101.

With reference to FIGS. 7 and 8, a secondary mask layer 730 may be formed on the substrate 101, temporarily filling the plurality of recesses R1. The secondary mask layer 730 may include a plurality of hole-patterns P1, exposing specific portions of the top surface 101TS of the substrate 101. Notably, none of the recesses R1 are exposed through the hole-patterns P1 of the secondary mask layer 730.

With reference to FIG. 9, an etching process (also referred to as the second substrate-etching process) may be performed, utilizing the secondary mask layer 730 as masks, to remove a portion of the substrate 101. This process results in the formation of the plurality of openings OP1.

With reference to FIGS. 10 and 11, the secondary mask layer 730 may be removed to expose the substrate 101. In some embodiments, the removal of the secondary mask layer 730 may be, for example, an ashing process or other applicable semiconductor processes. The plurality of recesses R1 and the plurality of openings OP1 may be simultaneously exposed after the removal of the secondary mask layer 730.

It should be noted that in the top-view diagram FIG. 10, the shallow features of the substrate 101, such as the plurality of recesses R1 and the plurality of openings OP1, are depicted using different section lines to enhance emphasis and improve clarity.

With reference to FIGS. 10 and 11, the plurality of recesses R1 and the plurality of openings OP1 may configure (or divide) the substrate 101 into a plurality of active portions AP and a plurality of supporting portions SP.

In a top-view perspective, each of the plurality of active portions AP may have an approximately line-shaped or rectangular cross-sectional profile. These active portions may be arranged along direction D1 and separated by the plurality of openings OP1. Additionally, the active portions may also be arranged along the direction D2 (or the Y direction) and separated by the plurality of recesses R1. Each of the plurality of supporting portions SP may have an approximately half-ring-shaped cross-sectional profile. Each supporting portion SP can simultaneously connect three adjacent active portions AP: two arranged along the direction D1 and one arranged along the direction D2, adjacent to the two active portions along the direction D1. Two adjacent supporting portions SP may be arranged along direction D2 and separated by the opening OP1.

Stated differently, in a top-view perspective, four active portions AP may form a set arranged in a diamond-shaped or rhombus-shaped configuration, with two arranged along the direction D1 and two arranged along the direction D2 (or Y direction, e.g., A3 and A4). The two active portions AP arranged along the direction D1 (e.g., A1 and A2) may be separated by the opening OP1. These two active portions arranged along the direction D1 are positioned between the two active portions arranged along the direction D2 (e.g., A3 and A4). Adjacent active portions (e.g., A1/A3, A2/A3, A1/A4, or A2/A4) are separated by the plurality of recesses R1.

The two supporting portions SP (e.g., SP1 and SP2) may be located centrally to connect the four active portions AP. In other words, the two supporting portions SP may be surrounded by the four active portions AP. Detailedly, the supporting portion SP1 may connect the active portions A1, A2, and A3 and may be surrounded by the plurality of recesses R1 along the direction D1. The supporting portion SP2 may connect the active portions A1, A2, and A4 and may be also surrounded by the plurality of recesses R1 along the direction D1. The two supporting portions SP1 and SP2 may be arranged along direction D2 and separated by the opening OP1. The two supporting portion SP (e.g., SP1 and SP2) may respectively have a half-ring-shaped cross-sectional profile with the openings oriented in opposite directions. For instance, in a top-view perspective, the opening of the supporting portion SP1 faces right, while the opening of supporting portion SP2 faces left.

In some embodiments, in a cross-sectional perspective, the bottom surface BS1 of the recesses R1 may be at the vertical level VL1 lower than the vertical level VL2 of the bottom surface BS2 of the opening OP1.

In some embodiments, the aspect ratio of the plurality of recesses R1 may be between about 4:1 and about 12:1. In some embodiments, the sidewalls SW1 of the plurality of recesses R1 may be substantially vertical. In some embodiments, the aspect ratio of the plurality of openings OP1 may be between about 3:1 and about 11:1. In some embodiments, the sidewalls SW2 of the plurality of openings OP1 may be substantially vertical.

In some comparative embodiments, the openings and the plurality of recesses may cause the active portions to become unstable due to their high aspect ratio, leading to potential shorts in the semiconductor device. In contrast, in the present disclosure, the plurality of supporting portions SP may provide additional structural stability to the plurality of active portions AP, preventing their collapse. Consequently, the yield and reliability of the semiconductor device 1A are significantly improved.

In some embodiments, a post-cleaning process similar to that illustrated in FIG. 5 may be performed after the formation of the plurality of openings OP1, and descriptions thereof are not repeated herein.

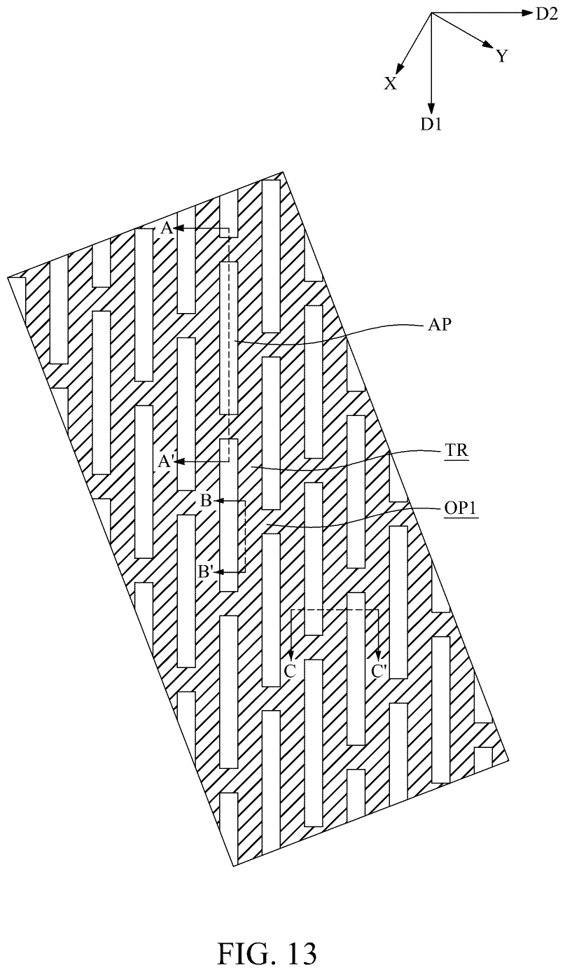

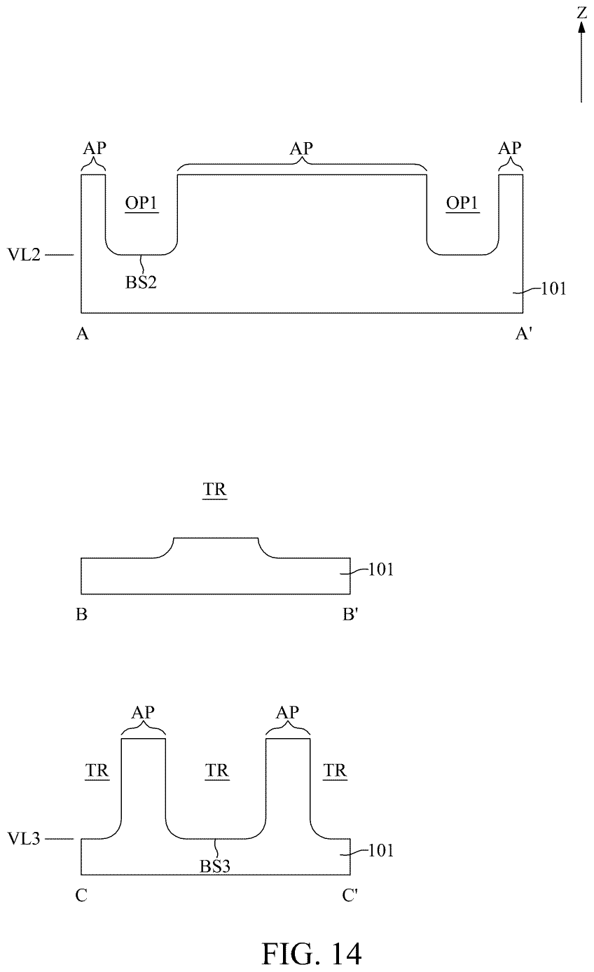

FIG. 13 illustrates, in a schematic top-view diagram, an intermediate semiconductor device in accordance with one embodiment of the present disclosure. FIGS. 14 to 20 are schematic cross-sectional view diagrams taken along lines A-A′, B-B′, and C-C′ in FIG. 13 illustrating part of the flow for fabricating the semiconductor device 1A in accordance with one embodiment of the present disclosure.

With reference to FIG. 1 and FIGS. 12 to 14, at step S15, an oxygen treatment may be performed to turn the plurality of supporting portions SP into a removable layer 750, and the removable layer 750 may be removed to form a plurality of trenches TR.

With reference to FIG. 12, the plurality of supporting portions SP of the substrate 101 may be oxidized through an oxygen treatment to form the removable layer 750. Additionally, the surfaces of the plurality of active portions AP, the plurality of recesses R1, and the plurality of openings OP1 may also be conformally oxidized during this oxygen treatment. These oxidized regions are collectively referred to as part of the removable layer 750. In some embodiments, the removable layer 750 may include silicon oxide.

In some embodiments, the oxygen treatment may involve an ashing process. This plasma-based process may expose the intermediate semiconductor device illustrated in FIG. 11 to oxygen plasma, effectively oxidizing the supporting portions SP and forming a thin silicon oxide layer on the substrate surface. This oxidation may occur when oxygen radicals interact with the silicon, converting it into silicon oxide. The ashing process may use oxygen gas alone or a combination of oxygen and nitrogen gases, with the latter enhancing the concentration of oxygen radicals. In some embodiments, the RF power applied during the ashing process may range from about 100 watts to about 1000 watts, while the substrate temperature may be maintained between about 20° C. and about 250° C.

It should be noted that in the top-view diagram FIG. 13, the shallow features of the substrate 101, such as the trenches TR, are depicted using different section lines to enhance emphasis and improve clarity.

With reference to FIGS. 13 and 14, the removable layer 750 may be removed, resulting in the connection of the plurality of recesses R1 along the direction D1 to form a plurality of trenches TR. Along the direction D2, adjacent trenches TR may interconnect through the opening OP1. In some embodiments, the bottom surface BS3 of the plurality of trenches TR may reside at a vertical level VL3 lower than the vertical level VL2 of the bottom surface BS2 of the plurality of openings OP1.

In some embodiments, the removal of the removable layer 750 may be achieved by applying vapor hydrogen fluoride to the removable layer 750. In some embodiments, the removal process may include a catalyst such as water vapor or alcohol to enhance the etching reaction for silicon oxide. For example, the presence of water vapor may facilitate the formation of reactive species that interact with silicon oxide. In some embodiments, the pressure of the removal process may be between about 75 torr and about 150 torr. In some embodiments, the temperature of the removal process may be between about 20° C. and about 30° C.

With reference to FIG. 1 and FIGS. 15 to 20, at step S17, an isolation structure 300 may be formed in the plurality of trenches TR and the plurality of openings OP1.

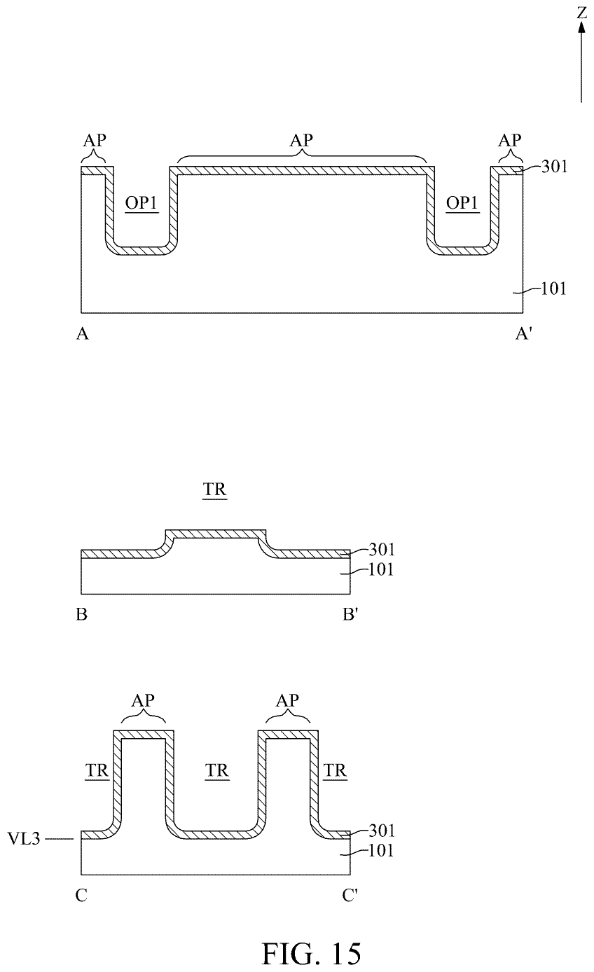

With reference to FIG. 15, a repairing layer 301 may be conformally formed on the substrate 101, on the plurality of trenches TR, and on the plurality of openings OP1. In some embodiments, the repairing layer 301 may be formed of, for example, silicon. In some embodiments, the repairing layer 301 may be formed by, for example, atomic layer deposition, chemical vapor deposition, or other applicable deposition processes. In some embodiments, the repairing layer 301 may fill seams of the plurality of plurality of trenches TR and the plurality of openings OP1. In some embodiments, the repairing layer 301 may serve as a buffer or a stress-reducing layer. The repairing layer 301 may be used to mitigate the mechanical stresses caused by the difference in thermal expansion coefficients between the substrate 101 and the insulating material which will be filled in later.

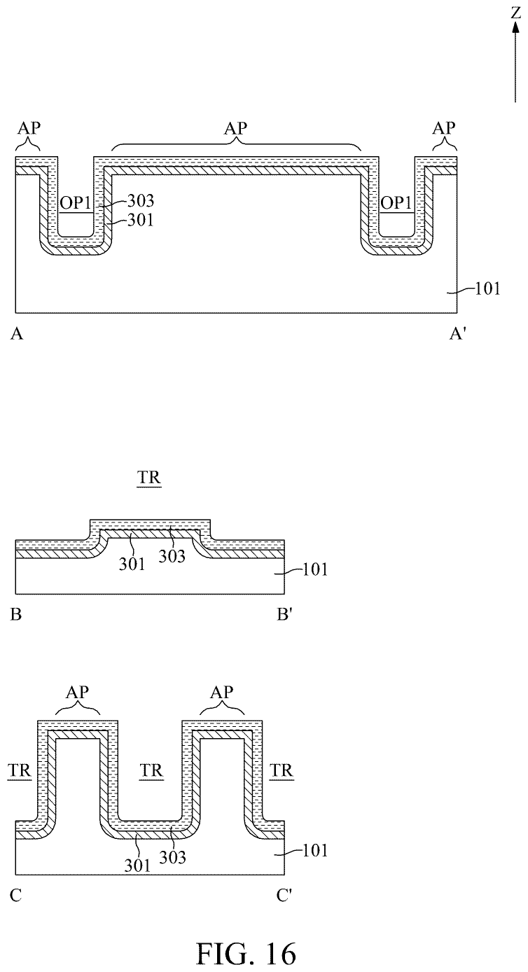

With reference to FIG. 16, an outer filling layer 303 may be conformally formed on the repairing layer 301. The plurality of trenches TR and the plurality of openings OP1 may not be completely filled by the outer filling layer 303. In some embodiments, the outer filling layer 303 may include silicon oxide or other applicable insulating materials.

In some embodiments, the outer filling layer 303 may be formed of, for example, silicon oxide. In some embodiments, the outer filling layer 303 may be formed by, for example, chemical vapor deposition, plasma-enhanced chemical vapor deposition, or other applicable deposition process.

In some embodiments, the outer filling layer 303 may be formed by a thermal oxidation and a subsequent deposition process. For example, the outer filling layer 303 may initially be formed by performing a rapid thermal oxidation to the intermediate semiconductor device illustrated in FIG. 16 in an oxide/oxynitride atmosphere to conformally form a thin layer (not shown for clarity) on the repairing layer 301. Subsequently, a flowable layer (not shown for clarity) may be conformally formed on the thin layer. Lastly, the flowable layer may be turned into the outer filling layer 303.

In some embodiments, the flowable layer may include compounds having unsaturated bonding such as double bonds and triple bonds. The flowable layer may be characterized as a soft jelly-like layer, a gel having liquid flow characteristics, or a liquid layer but is not limited thereto. The flowable layer may flow into and fill small substrate gaps without forming voids or weak seams. A thermal process may be subsequently performed to transform the flowable layer into the outer filling layer 303 by solidifying the flowable layer. The thermal process may break the unsaturated bonding into radicals, and the compounds may cross-link through the radicals. As a result, the flowable layer may be solidified. In some embodiments, the volume of the flowable layer may be reduced during the thermal process. Hence, the outer filling layer 303 may have greater density compared to the flowable layer. The outer filling layer 303 may be located at the position where the flowable layer previously occupied.

Alternatively, in some embodiments, the flowable layer may be a flowable silicon-and-nitrogen-containing layer. The flowable silicon-and-nitrogen-containing layer may be formed by mixing a carbon-free silicon-containing precursor with a radical-nitrogen precursor. The flowable nature of the flowable silicon-and-nitrogen-containing layer may allow the flowable silicon-and-nitrogen-containing layer to flow into narrow substrate gaps or narrow trenches. The temperature of the substrate 101 during the formation of the flowable silicon-and-nitrogen-containing layer may be less than 120° C., less than 100° C., less than 80° C., or less than 60° C.

The carbon-free silicon-containing precursor may be, for example, a silicon-and-nitrogen precursor, a silicon-and-hydrogen precursor, or a silicon-nitrogen-and-hydrogen-containing precursor. In some embodiments, the carbon-free silicon-containing precursor may also be oxygen-free. The lack of oxygen results in a lower concentration of silanol (Si—OH) groups in the flowable silicon-and-nitrogen-containing layer formed from the carbon-free silicon-containing precursor. Excess silanol moieties in the flowable silicon-and-nitrogen-containing layer may cause increased porosity and shrinkage during subsequent processing that remove the hydroxyl (—OH) moieties from the flowable silicon-and-nitrogen-containing layer.

In some embodiments, the carbon-free silicon-containing precursor may include silyl-amines such as H₂N(SiH₃), HN(SiH₃)₂, and N(SiH₃)₃. The flow rates of silyl-amines may be greater than or about 200 sccm, greater than or about 300 sccm, or greater than or about 500 sccm. These silyl-amines may be mixed with additional gases that may act as carrier gases, reactive gases, or both. Examples of these additional gases may include H₂, N₂, NH₃, He, and Ar.

In some embodiments, the carbon-free silicon-containing precursor may include silane either alone or mixed with other silicon (e.g., N(SiH₃)₃), hydrogen (e.g., H₂), and/or nitrogen (e.g., N₂, NH₃) containing gases.

In some embodiments, the carbon-free silicon-containing precursor may include disilane, trisilane, even higher-order silanes, and chlorinated silanes, alone or in combination with silyl-amines.

The radical-nitrogen precursor may be generated by delivering ammonia to a plasma region. The radical-nitrogen precursor may be subsequently delivered to mix with the carbon-free silicon-containing precursor. The flow rate of delivering ammonia to the plasma region may be greater than or about 300 sccm, greater than or about 500 sccm, or greater than or about 700 sccm. In some embodiments, gases such as nitrogen and hydrogen may be employed to adjust the nitrogen: hydrogen atomic flow ratio. In some embodiments, gases such as helium or argon may be employed as carrier gas for delivering ammonia to the plasma region.

In some embodiments, the radical-nitrogen precursor may be produced without using ammonia. Gases include one or more of hydrogen, nitrogen and hydrazine may be delivered to the plasma region to generate the radical-nitrogen precursor.

Subsequently, a cure process and an anneal process may be sequentially applied to the flowable silicon-and-nitrogen containing layer (i.e., the flowable layer) in an oxygen-containing atmosphere to convert the flowable silicon-and-nitrogen containing layer into the outer filling layer 303 formed of silicon oxide. In some embodiments, the substrate temperature of the cure process may be below or about 400° C. For example, the substrate temperature of the cure process may be between about 100° C. and about 200° C. In some embodiments, the substrate temperature of the anneal process may be between about 500° C. and about 1100° C. In some embodiments, the oxygen-containing atmosphere may include one or more oxygen-containing gases such as molecular oxygen, ozone, water vapor, hydrogen peroxide, and nitrogen-oxides (e.g., nitric oxide, nitrous oxide, etc.).

Alternatively, in some embodiments, the flowable layer may be formed by reacting vapor phase precursors with co-reactants. The flowable layer may have flow characteristics that can provide consistent fill of substrate gaps of the substrate 101. Subsequently, a post-deposition treatment may be performed, and the flowable layer may be physically densified and/or chemically converted to reduce its flowability. After the post-deposition treatment, the flowable layer may be turned into the outer filling layer 303. In some embodiments, the densified flowable layer may be considered to be solidified. In some embodiments, physically densifying the flowable layer may involve shrinking the flowable layer. In some embodiments, the post-deposition treatment may involve substituting chemicals in the flowable layer, which may result in a denser, higher volume outer filling layer 303.

In some embodiments, the flowable layer may be flowable silicon oxide, silicon nitride, or silicon oxynitride. In some embodiments, the flowable layer may be silicon carbide or silicon oxycarbide. In some embodiments, chamber pressure for formation of the flowable layer may be between about 1 Torr and 200 Torr, between 10 and 75 Torr, or about 10 Torr. In some embodiments, substrate temperature for formation of the flowable layer may be between about −20° C. and about 100° C., between about −20° C. and 30° C., or between about −10° C. and about 10° C.

In some embodiments, the vapor phase precursors may include silicon containing precursors or carbon containing precursors. The co-reactants may include oxidants, catalyst, surfactants, or inert carrier gases.

The silicon containing precursors may include, but are not limited to, silane, disilane, trisilane, hexasilane, cyclohexasilane, alkoxysilanes, aminosilanes, alkylsilanes, tetraisocyanatesilane (TICS), hydrogen silsesquioxane, T8-hydridospherosiloxane, or 1,2-dimethoxy-1,1,2,2-tetramethyldisilane.

The alkoxysilanes may include tetraoxymethylcyclotetrasiloxane (TOMCTS), octamethylcyclotetrasiloxane (OMCTS), tetraethoxysilane (TEOS), triethoxysilane (TES), trimethoxysilane (TriMOS), methyltriethoxyorthosilicate (MTEOS), tetramethylorthosilicate (TMOS), methyltrimethoxysilane (MTMOS), dimethyldimethoxysilane (DMDMOS), diethoxysilane (DES), dimethoxysilane (DMOS), triphenylethoxysilane, 1-(triethoxysilyl)-2-(diethoxymethylsilyl)ethane, tri-t-butoxylsilanol, hexamethoxydisilane (HMODS), hexaethoxydisilane (HEODS), or tert-butoxydisilane. The aminosilanes may include bis-tert-butylamino silane (BTBAS) or tris(dimethylamino)silane.

The carbon containing precursors may include, but are not limited to, trimethylsilane (3MS), tetramethylsilane (4MS), diethoxymethylsilane (DEMS), dimethyldimethoxysilane, methyl-triethoxysilane (MTES), methyl-trimethoxysilane, methyl-diethoxysilane, methyl-dimethoxysilane, trimethoxymethylsilane, dimethoxymethylsilane, or bis(trimethylsilyl)carbodiimide.

The oxidants may include, but are not limited to, ozone, hydrogen peroxide, oxygen, water, alcohols, nitric oxide, nitrous dioxide, nitrous oxide, carbon monoxide, or carbon dioxide. The alcohols may include, for example, methanol, ethanol, or isopropanol.

The catalyst may include, but are not limited to, proton donor catalyst, halogen-containing compounds, mineral acids, bases, chloro-diethoxysilane, methanesulfonic acid, trifluoromethanesulfonic acid, chloro-dimethoxysilane, pyridine, acetyl chloride, chloroacetic acid, dichloroacetic acid, trichloroacetic acid, oxalic acid, benzoic acid, or triethylamine. The proton donor catalyst may include nitric acid, hydrofluoric acid, phosphoric acid, sulphuric acid, hydrochloric acid, bromic acid, carboxylic acid derivatives, ammonia, ammonium hydroxide, hydrazine, or hydroxylamine. The halogen-containing compounds may include dichlorosilane, trichlorosilane, methylchlorosilane, chlorotriethoxysilane, chlorotrimethoxysilane, chloromethyldiethoxysilane, chloromethyldimethoxysilane, vinyltrichlorosilane, diethoxydichlorosilane, or hexachlorodisiloxane. The mineral acids may include formic acid or acetic acid. The bases may include phosphine.

The surfactants may include solvents, alcohols, ethylene glycol, or polyethylene glycol. The surfactants may be used to relieve surface tension and increase wetting of reactants on the substrate surface. The surfactants may also increase the miscibility of the vapor phase precursors with the other reactants.

The solvents may be non-polar or polar and protic or aprotic. The solvents may be matched to the choice of vapor phase precursors to improve the miscibility in the oxidants. Non-polar solvents may include alkanes and alkenes; polar aprotic solvents may include acetones and acetates; and polar protic solvents may include alcohols and carboxylic compounds.

Examples of solvents include, but not limited to, methanol, ethanol, isopropanol, acetone, diethylether, acetonitrile, dimethylformamide, dimethyl sulfoxide, tetrahydrofuran, dichloromethane, hexane, benzene, toluene, isoheptane and diethylether. In some embodiments, the solvents may be introduced prior to the other reactants.

The inert carrier gases may include nitrogen, helium, or argon.

The post-deposition treatment may cross-link and remove terminal groups such as —OH and —H groups in the flowable layer, therefore increasing the density and hardness of the flowable layer. The post-deposition treatment may be thermal curing, exposure to a downstream or direct plasma, exposure to ultraviolet or microwave radiation, or exposure to another energy source.

While using thermal curing as the means of the post-deposition treatment, the temperature of thermal curing may be between about 200° C. and 600° C. The post-deposition treatment may be performed in an inert environment, an oxidizing environment, a nitridizing environment, or a mix of oxidizing and nitridizing environment. The inert environment may include argon or helium. The oxidizing environment may include oxygen, ozone, water, hydrogen peroxide, nitrous oxide, nitric oxide, nitrogen dioxide, carbon monoxide, carbon dioxide. The nitridizing environment may include nitrogen, ammonia, nitrous oxide, nitric oxide, and nitrogen dioxide. The pressure of thermal curing may be between about 0.1 Torr and about 10 Torr.

While using the exposure to a downstream or direct plasma as the means of the post-deposition treatment, the plasma may be an inert plasma or a reactive plasma. The inert plasma may be helium and argon plasma. The reactive plasma may be oxidizing plasma including oxygen and steam, or hydrogen-containing plasma including hydrogen and a diluent such as inert gas. In some embodiments, the temperature during plasma exposure may be about 25° C. or higher. In some embodiments, the temperature during plasma exposure may be between about −15° C. and about 25° C.

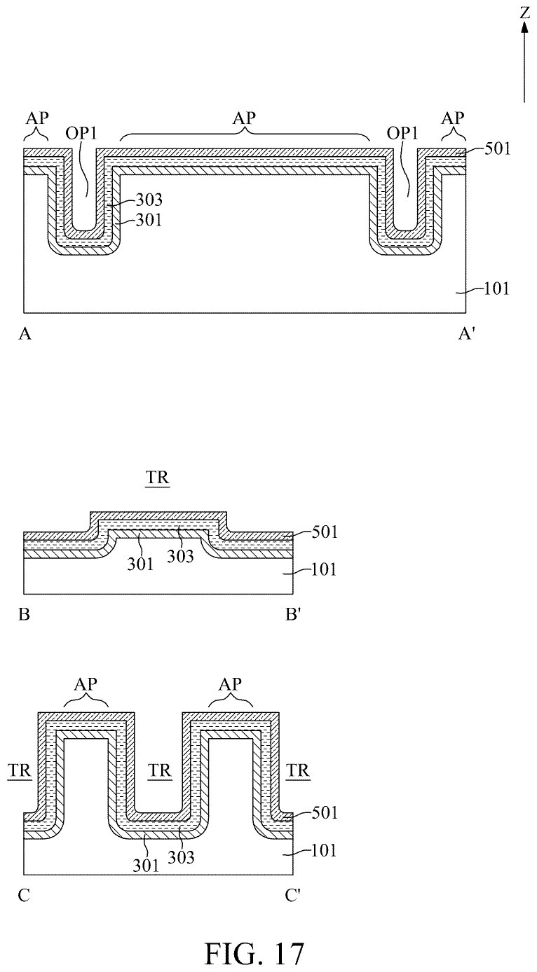

With reference to FIG. 17, a layer of first filling material 501 may be conformally formed on the outer filling layer 303. The layer of first filling material 501 may not completely fill the plurality of trenches TR and the plurality of openings OP1. In some embodiments, the first filling material 501 may be formed of a material having etching selectivity to the outer filling layer 303. In some embodiments, the first filling material 501 may include silicon nitride or other applicable insulating material. In some embodiments, the first filling material 501 may serve as a stop layer for the subsequent planarization process or etching process. In some embodiments, the first filling material 501 may be formed by, for example, atomic layer deposition, chemical vapor deposition, or other applicable deposition process.

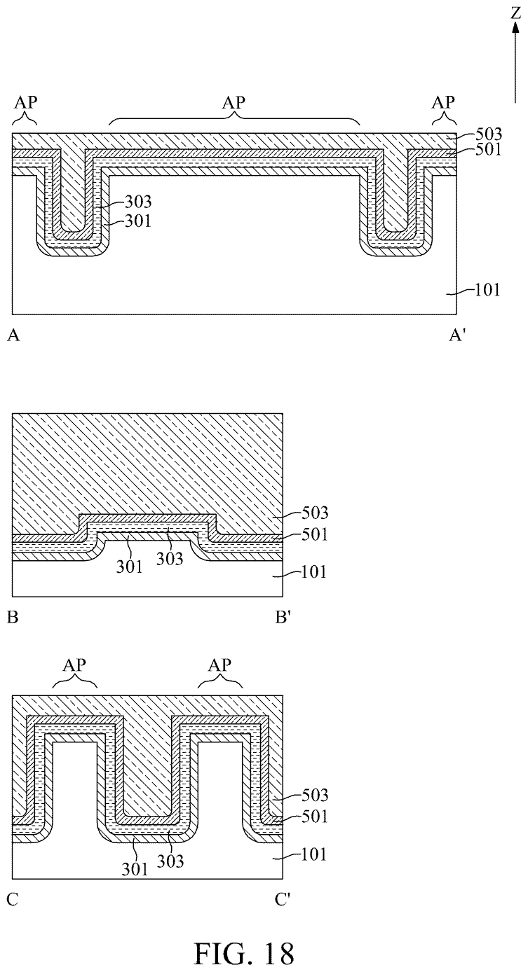

With reference to FIG. 18, a layer of second filling material 503 may be formed on the layer of first filling material 501. The layer of second filling material 503 may completely fill the plurality of trenches TR and the plurality of openings OP1. In some embodiments, the second filling material 503 may be formed of a material having etching selectivity to the first filling material 501. In some embodiments, the second filling material 503 may include the same material as the outer filling layer 303. In some embodiments, the second filling material 503 may include silicon oxide or other applicable material. In some embodiments, the layer of second filling material 503 may be formed by, for example, chemical vapor deposition, plasma-enhanced chemical vapor deposition, or other applicable deposition processes.

In some embodiments, a high aspect ratio process may be performed to deposit the layer of second filling material 503, ensuring complete filling of the plurality of trenches TR and the plurality of openings OP1 and covering the layer of first filling material 501. The high aspect ratio process may involve two stages. During the first stage, a low deposition rate is employed to achieve a more uniform trench filling and reduce the likelihood of void formation. In the second stage, a rapid deposition rate is used to increase overall production efficiency by reducing the deposition time. This high aspect ratio process incorporates both slower and higher deposition rate stages, strategically utilizing the slower deposition rate when it is advantageous for reducing defects and the higher deposition rate for shorter deposition time. Additionally, in some embodiments, the pressure during the high aspect ratio process may range between about 200 Torr and about 760 Torr, while the temperature may be between about 400° C. and about 570° C.

In some embodiments, a two-stage anneal process may be performed after the high aspect ratio process. During the first stage of the two-stage anneal, a lower temperature environment containing one or more oxygen-containing species, such as water, oxygen, nitric oxide, or nitrous oxide, is used. This first stage aims to rearrange and strengthen the silicon oxide network, thereby preventing the formation of voids and the opening of weak seams in the plurality of trenches TR and the plurality of openings OP1. Additionally, the lower temperature in the first stage prevents oxygen from reacting with the trench walls and other parts of the substrate 101, which could lead to the formation of undesirable oxide layers.

Subsequently, in the second stage of the two-stage anneal, a higher temperature environment without oxygen is employed. The second stage serves to further rearrange the structure of the second filling material 503 and drive out moisture, both of which increase the density of the layer of second filling material 503. The environment during the second stage may be, for example, substantially pure nitrogen, a mixture of nitrogen and noble gases (e.g., helium, neon, argon, or xenon), or a substantially pure noble gas. It may also include reducing gases like hydrogen or ammonia. The second stage facilitates high-temperature densification without causing oxidation of the substrate 101.

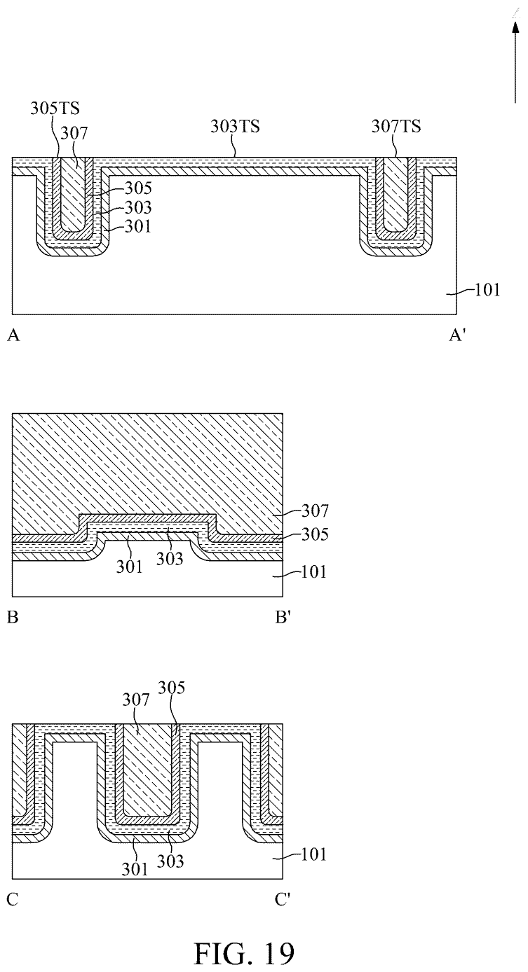

With reference to FIG. 19, after the two-stage anneal, a planarization process, such as chemical mechanical polishing, may be performed until the top surface 303TS of the outer filling layer 303 is exposed to remove excess material and provide a substantially flat surface for subsequent processing steps. The outer filling layer 303 may serve as a stop layer in the planarization process. After the planarization process, the remaining first filling material 501 may be referred to as a plurality of center layers 305 and the remaining second filling material 503 may be referred to as a plurality of inner filling layers 307. The top surface 303TS of the outer filling layer 303, the top surface 305TS of the plurality of center layers 305, and the top surface 307TS of the plurality of inner filling layers 307 may be substantially coplanar in the current stage.

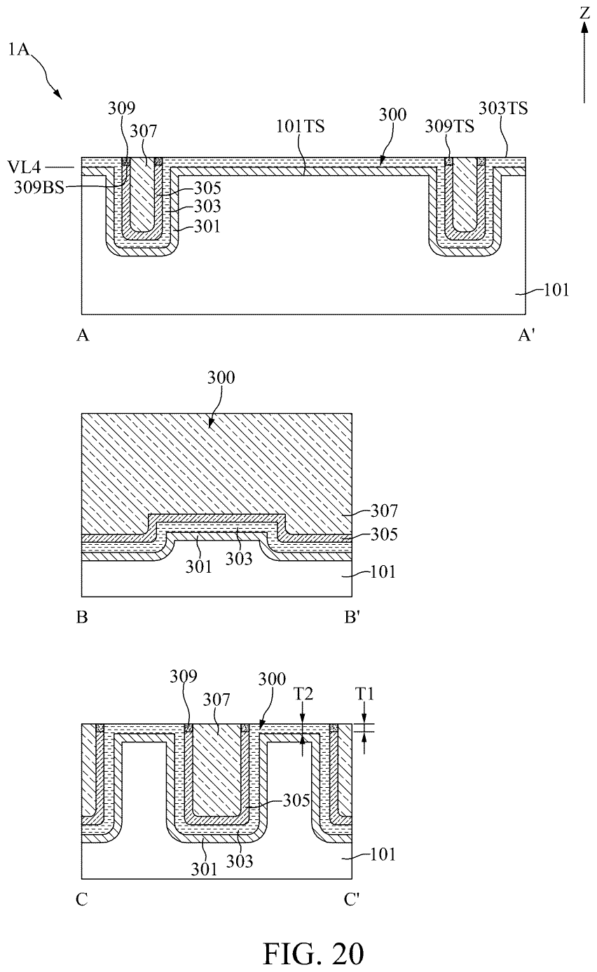

With reference to FIG. 20, a surface oxidation process may be performed to oxidize the top ends of the plurality of center layers 305, which are formed of silicon nitride in the present embodiment. The oxidized ends of the plurality of center layers 305 may be referred to as a plurality of protection layers 309. Stated differently, the plurality of protection layers 309 may be disposed on the plurality of center layers 305, respectively and correspondingly. The repairing layer 301, the outer filling layer 303, the center layer 305, the inner filling layer 307, and the plurality of protection layers 309 together configure the isolation structure 300.

In some embodiments, the surface oxidation process may be a low-temperature plasma oxidation process. The low-temperature plasma oxidation process for converting silicon nitride into silicon oxide may involve several steps and specific process conditions. First, the intermediate semiconductor device illustrated in FIG. 19 may be loaded into a plasma-enhanced chemical vapor deposition chamber maintained at a low temperature between about 200° C. and about 400° C. Then, a gas mixture of oxygen and an inert gas, such as nitrogen or argon, may be introduced into the chamber with controlled flow rates. The flow rate of oxygen may be set in the range of about 10 standard cubic centimeter per minute (sccm) and about 100 sccm, while the inert gas flow rate can vary from about 50 sccm to about 500 sccm. Radio frequency (RF) power may be applied to generate a low-temperature plasma with a power level of about 50 watts and about 300 watts. The RF power excites the gas mixture, creating reactive species, including oxygen radicals, which play a crucial role in the low-temperature plasma oxidation process.

During the low-temperature plasma oxidation process, the oxygen radicals react with the silicon nitride surface, converting it into silicon oxide without the need for high temperatures. The low-temperature plasma oxidation process is self-limiting, meaning the reaction rate decreases as the silicon nitride layer is converted into silicon oxide. The oxidation time may be carefully controlled to achieve the desired thickness of the plurality of protection layers 309, and it typically ranges from a few minutes to tens of minutes, depending on the required film thickness and properties. After the oxidation step, the plasma is deactivated, and a purge gas, usually nitrogen, is introduced into the chamber to remove any residual reactive species and by-products.

For brevity, clarity, and convenience of description, only one protection layer 309 is described.

With reference to FIG. 20, the bottom surface 309BS of the protection layer 309 may be at a vertical level VL4 higher than the top surface 101TS of the substrate 101 or the top surface 301TS of the repairing layer 301. In some embodiments, the thickness T1 of the protection layer 309 may be less than the thickness T2 of the outer filling layer 303. In some embodiments, the ratio of the thickness T1 of the protection layer 309 to the thickness T2 of the outer filling layer 303 may be between about 0.1 and about 0.8 or between about 0.3 and about 0.6.

The plurality of protection layers 309 serve to prevent the underlying center layers 305 from being removed during the subsequent etching process. The top surface 303TS of the outer filling layer 303 and the top surface 309TS of the protection layer 309 may be substantially coplanar after subsequent etching process. That is, the surface of the semiconductor device 1A may be intact and substantially flat for subsequent semiconductor processes. As a result, the reliability of the semiconductor device 1A may be improved.

In some comparative embodiments, if the protection layer 309 is not present, the center layer 305, which may be formed of silicon nitride, may also be removed during subsequent etching process, resulting in small recesses. As a consequence, the reliability of the semiconductor device may be affected.

One aspect of the present disclosure provides a semiconductor device including a substrate including at least four active portions, and at least two supporting portions connecting the at least four active portions. Two of the at least four active portions are arranged along a first direction and separated by an opening in a top-view perspective. The other two of the at least four active portions are arranged along a second direction perpendicular to the first direction, separated by the opening, and with the two of the at least four active portions arranged along the first direction interposed therebetween in a top-view perspective. The other two of the at least four active portions arranged along the second direction and the two of the at least four active portions arranged along the first direction are separated by a plurality of recesses in a top-view perspective. The at least two supporting portions are arranged along the second direction, separated by the opening, and respectively connecting to three of the at least four active portions in a top-view perspective.

Another aspect of the present disclosure provides a semiconductor device including a substrate including four active portions arranged in a rhombus-shaped configuration in a top-view perspective, and two supporting portions centrally positioned and surrounded by the four active portions in a top-view perspective, with the two supporting portions respectively connecting three of the four active portions.

Another aspect of the present disclosure provides a method for fabricating a semiconductor device including providing a substrate; performing a first substrate-etching process using a primary mask layer as a mask to form a plurality of recesses in the substrate; forming a secondary mask layer on the substrate and filling the plurality of recesses; performing a second substrate-etching process using the secondary mask layer as a mask to form a plurality of openings in the substrate and configure a plurality of active portions and a plurality of supporting portions, wherein, in a top-view perspective, the plurality of active portions are arranged along a first direction and a second direction perpendicular to the first direction, the plurality of active portions arranged along the first direction are separated by the plurality of openings, the plurality of active portions arranged along the second direction are separated by the plurality of recesses, and the plurality of supporting portions surround the plurality of openings and respectively connects three of the plurality of active portions; performing an oxygen treatment to turn the plurality of supporting portions into a removable layer; and removing the removable layer to turn the plurality of recesses into a plurality of trenches.

Due to the design of the semiconductor device of the present disclosure, the plurality of supporting portions SP may provide additional structural stability to the plurality of active portions AP, preventing their collapse. Consequently, the yield and reliability of the semiconductor device 1A may be significantly improved.

Although the present disclosure and its advantages have been described in detail, it should be understood that various changes, substitutions and alterations can be made herein without departing from the spirit and scope of the disclosure as defined by the appended claims. For example, many of the processes discussed above can be implemented in different methodologies and replaced by other processes, or a combination thereof.

Moreover, the scope of the present application is not intended to be limited to the particular embodiments of the process, machine, manufacture, composition of matter, means, methods and steps described in the specification. As one of the ordinary skill in the art will readily appreciate from the disclosure of the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods, and steps.

What is claimed is:

1. A semiconductor device, comprising:
a substrate comprising:
at least four active portions; and
at least two supporting portions connecting the at least four active portions;
wherein two of the at least four active portions are arranged along a first direction and separated by an opening in a top-view perspective;
wherein the other two of the at least four active portions are arranged along a second direction perpendicular to the first direction, separated by the opening, and with the two of the at least four active portions arranged along the first direction interposed therebetween in a top-view perspective;
wherein the other two of the at least four active portions arranged along the second direction and the two of the at least four active portions arranged along the first direction are separated by a plurality of recesses in a top-view perspective;
wherein the at least two supporting portions are arranged along the second direction, separated by the opening, and respectively connecting to three of the at least four active portions in a top-view perspective.

2. The semiconductor device of claim 1, wherein the at least four active portions respectively has a line-shaped or rectangular cross-sectional profile in a top-view perspective.

3. The semiconductor device of claim 1, wherein the at least two supporting portions respectively has a half-ring-shaped cross-sectional profile in a top-view perspective.

4. The semiconductor device of claim 1, wherein a bottom surface of the opening and a bottom surface of the plurality of recesses are at different vertical levels.

5. The semiconductor device of claim 1, wherein a bottom surface of the opening is at a vertical level higher than a vertical level of a bottom surface of the plurality of recesses.

6. The semiconductor device of claim 1, wherein an aspect ratio of the plurality of recesses is between about 4:1 and about 12:1.

7. The semiconductor device of claim 1, wherein an aspect ratio of the plurality of recesses is between about 3:1 and about 11:1.

8. The semiconductor device of claim 1, wherein the substrate comprises silicon, germanium, silicon germanium, silicon carbon, or silicon germanium carbon.

9. The semiconductor device of claim 1, wherein a crystal orientation of the substrate is <100>, <110>, or <111>.

10. The semiconductor device of claim 3, wherein the opening is surrounded by the at least two supporting portions in a top-view perspective.

11. A semiconductor device, comprising:
a substrate comprising:
four active portions arranged in a rhombus-shaped configuration in a top-view perspective; and
two supporting portions centrally positioned and surrounded by the four active portions in a top-view perspective, with the two supporting portions respectively connecting three of the four active portions.

12. The semiconductor device of claim 11, wherein the four active portions respectively has a line-shaped or rectangular cross-sectional profile in a top-view perspective.

13. The semiconductor device of claim 12, wherein the two supporting portions respectively has a half-ring-shaped cross-sectional profile in a top-view perspective.

14. The semiconductor device of claim 13, wherein two of the four active portions are arranged along a first direction and the other two of the four active portions are arranged along a second direction perpendicular to the first direction.

15. The semiconductor device of claim 14, further comprising an opening positioned in the substrate to separate the two of the four active portions along the first direction.

16. The semiconductor device of claim 15, further comprising a plurality of recesses positioned in the substrate to separate the two of the four active portions and the other two of the four active portions.

17. The semiconductor device of claim 16, wherein the opening are surrounded by the two supporting portions.

18. The semiconductor device of claim 17, wherein the two supporting portions are surrounded by the plurality of recesses along the first direction.

19. The semiconductor device of claim 18, wherein a bottom surface of the opening and a bottom surface of the plurality of recesses are at different vertical levels.

20. The semiconductor device of claim 18, wherein a bottom surface of the opening is at a vertical level higher than a vertical level of a bottom surface of the plurality of recesses.
